(19) United States
(12) Patent Application Publication
(10) Pub. No.: US 2025/0246700 A1
(43) Pub. Date: Jul. 31, 2025

(54) SEPARATOR DEFECT INSPECTION APPARATUS FOR SECONDARY BATTERY

(71) Applicant: SK ON CO., LTD., Seoul (KR)

(72) Inventors: Hwan Cheol YOU, Daejeon (KR); Eun Jeong KIM, Daejeon (KR); Seo Jeong PARK, Daejeon (KR); Chang Hyun HWANG, Daejeon (KR); Hyung Joon KIM, Daejeon (KR)

(21) Appl. No.: 18/991,734

(22) Filed: Dec. 23, 2024

(30) Foreign Application Priority Data
Jan. 29, 2024 (KR) 10- 2024-0013476
Jun. 11, 2024 (KR) 10- 2024-0075862

(51) Int. Cl. H01M 10/42; G01R 31/52

(52) U.S. Cl. CPC H01M 10/4285; G01R 31/52

(57) ABSTRACT

Proposed is a separator defect inspection apparatus for a secondary battery. The separator defect inspection apparatus includes a base plate that is provided to be movable toward a secondary battery and a compression unit that provides a localized protrusion structure to the base plate to compress a predetermined area of the secondary battery.

### CROSS REFERENCE TO RELATED APPLICATION

The present application claims priority to Korean Patent Application No. 10-2024-0075862, filed Jun. 11, 2024, which claims priority to Korean Patent Application No. 10-2024-0013476 filed Jan. 29, 2024, the entire contents of which is incorporated herein for all purposes by this reference.

### BACKGROUND OF THE DISCLOSURE

### 1. Field of the Disclosure

The present disclosure relates to a separator defect inspection apparatus for a secondary battery.

### 2. Description of the Related Art

Secondary batteries can be manufactured by injecting an electrolyte into a battery container where an electrode assembly is housed and then sealing the battery container. In such manufactured secondary batteries, various defects may occur during the assembly process, manufacturing process, or use thereof due to different causes.

Low-voltage defects, a phenomenon in which a completely manufactured battery exhibits a voltage drop behavior of a self-discharge rate or higher, may also occur when assembling secondary batteries, which may result from damage to separators.

Damage to secondary battery separators may occur primarily in specific areas (hereinafter referred to as “defect-prone areas”) of battery cells during the battery manufacturing processes. Such defects may be unproblematic for now because positive and negative electrodes are prevented from making contact with each other due to the thickness of a separator but, in the future, may cause an internal short circuit (a short where positive and negative electrodes make contact). Hence, there is a demand for physically compressing defect-prone areas of secondary batteries to intentionally cause an internal short circuit, thereby screening for defects.

Although vision inspection is commonly performed on defects in secondary battery separators, in the case of specific secondary batteries, screening for defects through vision inspection is challenging due to internal defects. Accordingly, defect inspection can be performed through physical compression.

In this method of inspecting for defects in secondary batteries by compression, the surface of a secondary battery is compressed, and then a leakage current generated from the secondary battery is measured, thereby screening for defects.

### DOCUMENT OF RELATED ART

### Patent Document

(Patent Document 1) KR 10-2023-0075796 A

### SUMMARY OF THE INVENTION

According to one aspect of the present disclosure, provided may be a separator defect inspection apparatus for a secondary battery, the separator defect inspection apparatus enabling a localized external force to be applied to a defect-prone area of a secondary battery, thereby compressing only a required area without increasing the surface pressure of the entire secondary battery during a defect inspection.

In addition, provided may be a separator defect inspection apparatus for a secondary battery, the separator defect inspection apparatus allowing a localized compression position to move freely even when the position of a compression area needs to be changed due to a change in a defect-prone area of a secondary battery, thereby flexibly corresponding to an inspection position.

According to another aspect of the present disclosure, provided may be a separator defect inspection apparatus for a secondary battery, the separator defect inspection apparatus capable of being widely applied to electric vehicles, battery charging stations, and other fields of green technology, such as solar and wind power generation using batteries.

A separator defect inspection apparatus for a secondary battery, according to one embodiment of the present disclosure, may include: a base plate that is provided to be movable toward a secondary battery; and a compression unit that provides a localized protrusion structure to the base plate to compress a predetermined area of the secondary battery.

In this case, the compression unit may be provided to be movable on the base plate along a longitudinal direction of the base plate.

In addition, the compression unit may be guided on the base plate by a guide unit.

In addition, the compression unit may be provided in a shape that surrounds the base plate from the outside, and the guide unit may include: a guide groove that is provided on one surface of the base plate; and a guide protrusion that is provided on one surface of the compression unit to engage slidably with the guide groove.

In addition, the separator defect inspection apparatus may further include a position fixing unit so that the compression unit is fixed to a specific position of the base plate.

In addition, the position fixing unit may include: a first position fixing hole that is provided on one surface of the base plate at predetermined intervals along the longitudinal direction of the base plate; a second position fixing hole that is provided on one surface of the compression unit to correspond to the first position fixing hole; and a fixing pin that passes through the second position fixing hole and is inserted into the first position fixing hole to positionally fix the compression unit to the base plate.

In addition, the fixing pin may include: a head portion; and a pin portion that extends from the head portion and is provided insertably into the first and second position fixing holes.

In addition, at least a portion of an upper part of the head portion may include an inclined portion whose width gradually increases from top to bottom to guide the secondary battery to enter in position.

In addition, a maximum protrusion of the inclined portion may be provided such that the fixing pin, when inserted into the first and second position fixing holes, protrudes further compared to the respective outer surfaces of the base plate and the compression unit in the thickness directions thereof.

In addition, the separator defect inspection apparatus may further include an interleaving sheet that is removably inserted between the separator defect inspection apparatus and another neighboring separator defect inspection apparatus to protect the secondary battery.

In addition, the interleaving sheet may include a main body portion that is inserted between a plurality of neighboring separator defect inspection apparatuses and is bent several times to provide an accommodation space capable of accommodating the secondary battery thereinside.

In addition, the interleaving sheet may further include a side portion that covers a lateral lower part of the accommodation space and connects opposing surfaces of the main body portion that are spaced from each other.

In addition, the side portion may be provided to have a height lower than that of a tab portion of the secondary battery accommodated in the main body portion.

In addition, the side portion may include a plurality of creases that are provided such that the side portion folds along a compression direction.

The features and advantages of the present disclosure will become more apparent from the following detailed description based on the accompanying drawings.

All terms or words used in the specification and the appended claims should not be construed as being limited to general and dictionary meanings, but will be interpreted based on the meanings and concepts consistent with the technical idea of the present disclosure on the basis of the principle that any inventor is allowed to define the terms appropriately for the best explanation.

According to one embodiment of the present disclosure, a localized external force is enabled to be applied to a defect-prone area of a secondary battery so that only a required area can be selectively compressed without increasing the surface pressure of the entire secondary battery during a defect inspection for a separator, thus improving the defect inspection characteristics for the separator.

In addition, a localized compression position is allowed to move easily even when the position of a compression area needs to be changed due to a change in the defect-prone area of the secondary battery, thereby flexibly corresponding to an inspection position.

### BRIEF DESCRIPTION OF THE DRAWINGS

FIG. 1 is an exploded perspective view illustrating a separator defect inspection apparatus for a secondary battery, according to one embodiment of the present disclosure;

FIG. 2 is a perspective view illustrating a state in which a secondary battery is arranged between separator defect inspection apparatuses for a secondary battery, according to one embodiment of the present disclosure;

FIG. 3 is a cross-sectional view illustrating an engagement structure of a separator defect inspection apparatus for a secondary battery, according to one embodiment of the present disclosure;

FIG. 4 is a reference view schematically illustrating a state in which a secondary battery is inserted between a plurality of separator defect inspection apparatuses;

FIG. 5 is a perspective view illustrating an interleaving sheet of a separator defect inspection apparatus for a secondary battery, according to one embodiment of the present disclosure;

FIG. 6 is a side view illustrating a pre-compressed state of a secondary battery, in which an interleaving sheet and the secondary battery are installed between a plurality of separator defect inspection apparatuses for a secondary battery; and

FIG. 7 is a view illustrating a functional state in which, in the condition illustrated in FIG. 6, the plurality of separator defect inspection apparatuses moves to compress the secondary battery.

### DESCRIPTION OF THE PREFERRED EMBODIMENTS

The terms used herein to describe one embodiment of the present disclosure are not intended to limit the disclosure. It should be noted that singular expressions include plural expressions unless the context indicates otherwise.

In assigning reference numerals to elements in the drawings, the same elements are assigned the same reference numerals as much as possible throughout different drawings, and like elements are assigned like reference numerals.

In the drawings, the shape and size of elements may be schematically or exaggeratedly drawn to describe the embodiment. As used herein, terms such as “comprise”, “comprising”, “include”, “including”, “may include”, and the like specify the presence of stated features (for example, integers, functions, operations, or elements such as parts), but do not preclude the addition of other features.

Terms such as “one”, “other”, “another”, “first”, “second” and the like are only used to distinguish one element from another, and these elements are not limited by such terms.

Hereinafter, one embodiment of the present disclosure will be described in detail with reference to the accompanying drawings.

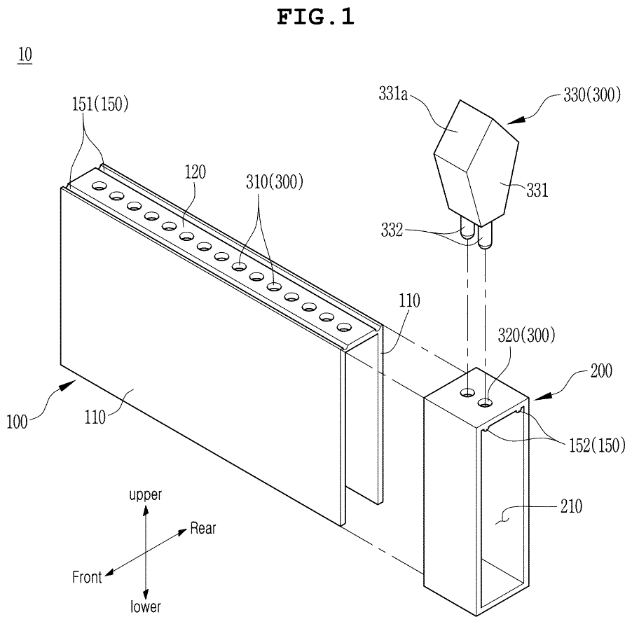

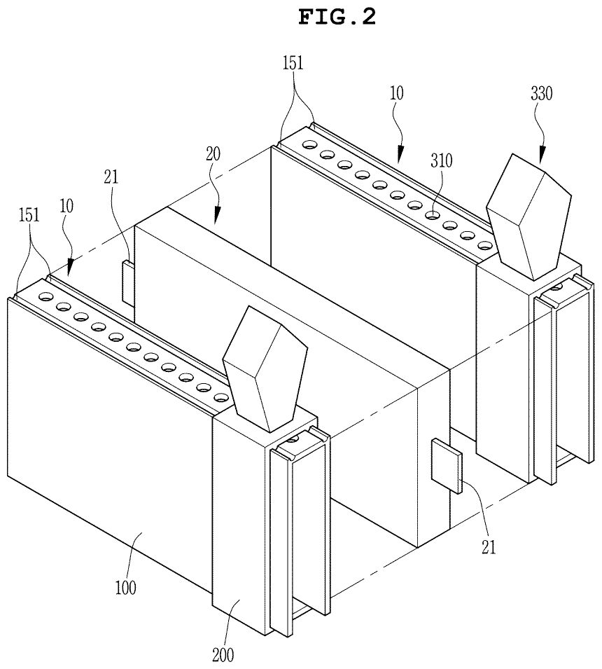

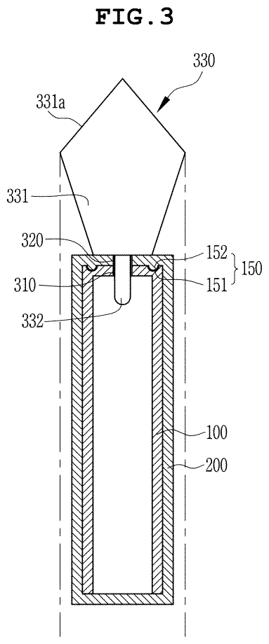

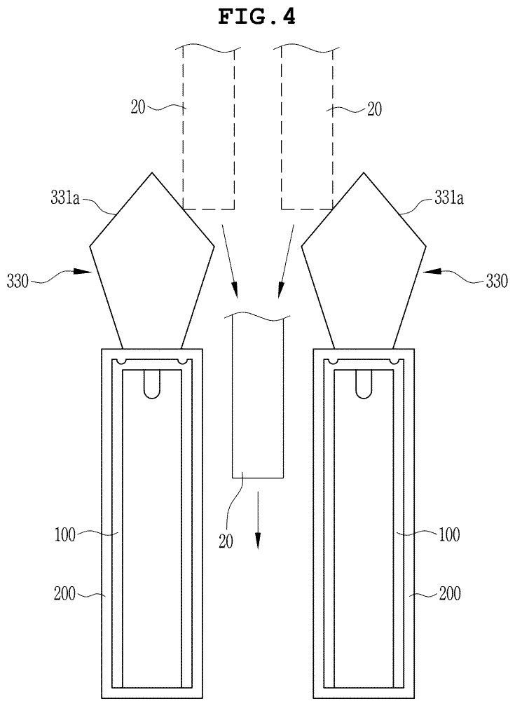

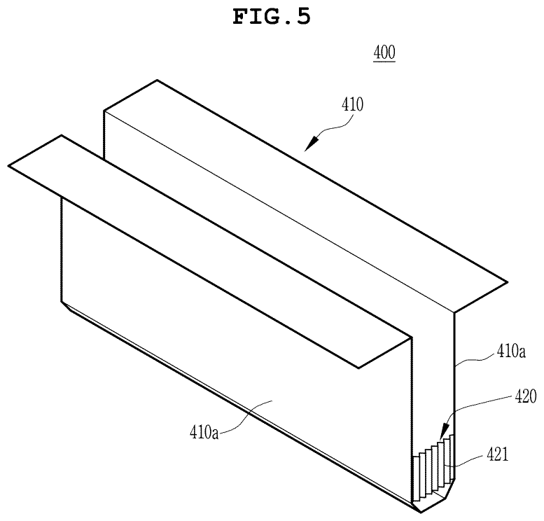

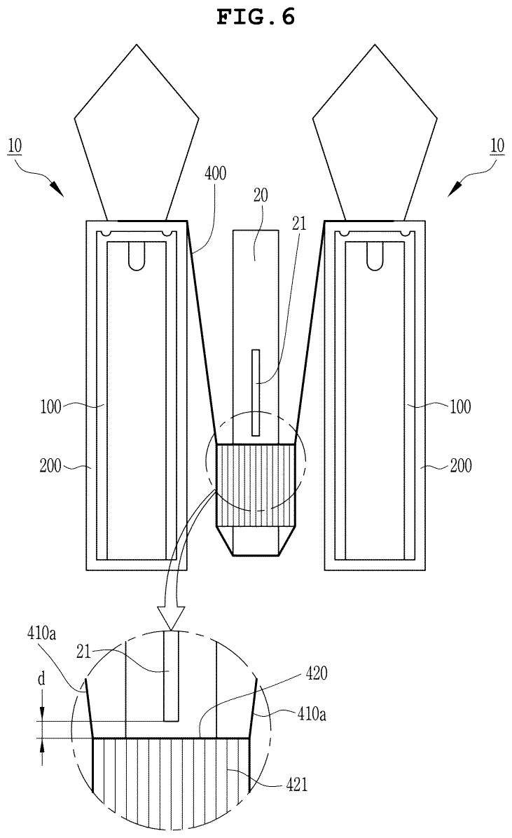

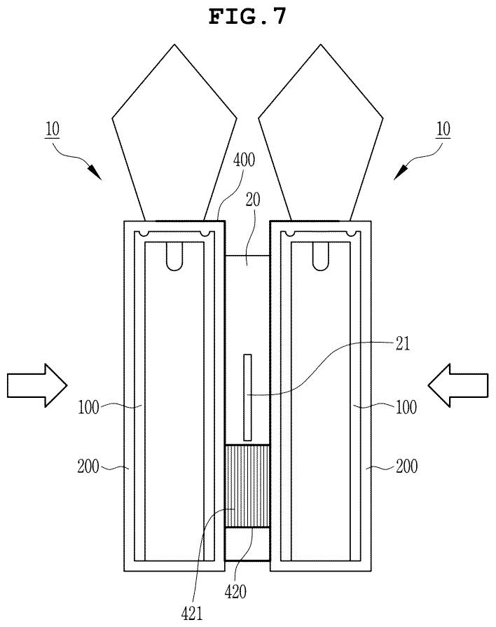

FIG. 1 is an exploded perspective view illustrating a separator defect inspection apparatus for a secondary battery, according to one embodiment of the present disclosure; FIG. 2 is a perspective view illustrating a state in which a secondary battery is arranged between separator defect inspection apparatuses for a secondary battery, according to one embodiment of the present disclosure; FIG. 3 is a cross-sectional view illustrating an engagement structure of a separator defect inspection apparatus for a secondary battery, according to one embodiment of the present disclosure; FIG. 4 is a reference view schematically illustrating a state in which a secondary battery is inserted between a plurality of separator defect inspection apparatuses; FIG. 5 is a perspective view illustrating an interleaving sheet of a separator defect inspection apparatus for a secondary battery, according to one embodiment of the present disclosure; FIG. 6 is a side view illustrating a pre-compressed state of a secondary battery, in which an interleaving sheet and the secondary battery are installed between a plurality of separator defect inspection apparatuses for a secondary battery; and FIG. 7 is a view illustrating a functional state in which, in the condition illustrated in FIG. 6, the plurality of separator defect inspection apparatuses moves to compress the secondary battery.

A separator defect inspection apparatus 10 for a secondary battery, according to one embodiment of the present disclosure, may include: a base plate 100 that is provided to be movable toward a secondary battery 20; and a compression unit 200 that provides a localized protrusion structure to an exterior of the base plate 100 to compress a predetermined area of the secondary battery 20.

As illustrated in FIGS. 1 and 2, the base plate 100 is a structure configured to compress the secondary battery 20. During a compression test of the secondary battery 20, this base plate 100 may be provided to be movable toward the secondary battery 20 while being arranged to be spaced from the secondary battery 20 at predetermined intervals.

In other words, as illustrated in FIG. 2, a plurality of base plates 100 may be arranged in positions facing both opposing surfaces of the secondary battery 20 so that each of both the opposing surfaces of the secondary battery 20 is compressed during the compression test of the secondary battery 20. In addition, the plurality of base plates 100 may be arranged to be spaced from each other while the secondary battery 20 is positioned therebetween.

Furthermore, once the compression test begins, the base plate 100 may be provided to be movable toward the secondary battery 20 to compress the secondary battery 20 at a position spaced from the secondary battery 20.

Specifically, referring to FIG. 1, the base plate 100 may have walls 110 that are formed to apply an external force to the secondary battery 20. These walls 110 may be formed respectively on the front and rear sides of the base plate 100 to face the secondary battery 20 while being spaced from each other. In addition, the base plate 100 may have an upper surface 120 that connects a plurality of walls 110 spaced from each other.

Although a lower surface may be provided at the lower side of the base plate 100 so that the plurality of walls 110, formed to be spaced from each other, is connected at the lower part thereof, the base plate 100 may be alternatively provided in an open structure, as illustrated in the drawings of the present disclosure. Accordingly, the base plate 100 may be provided in an inverted U-shape where the lower side is open.

For reference, the terms upper, lower, front, and rear, used herein, may be interpreted to mean the directions shown by the arrows in FIG. 1.

The compression unit 200 may provide the localized protrusion structure that protrudes further toward the secondary battery 20 compared to the outer walls 110 of the base plate 100 so that the predetermined area (for example, defect-prone areas) of the secondary battery 20 is compressed.

For reference, the localized protrusion structure, according to the present disclosure, is configured to provide a structure in which only a specific area of the base plate 100 protrudes. That is, when performing defect inspections on secondary batteries, the localized protrusion structure enables a localized external force to be applied only to defect-prone areas of secondary batteries (for example, areas adjacent to tabs of secondary batteries) without compressing other areas where defect inspections are unnecessary, thereby compressing only required areas (defect-prone areas) without increasing the surface pressure of the entire secondary battery during the defect inspection.

In this case, the compression unit 200 may be fixed to and engage with the base plate 100 not to move thereon, thereby providing the localized protrusion structure. However, the compression unit 200 may engage movably with the base plate 100 thereon.

In addition, the compression unit 200 provided may be made of a material, at least a part of which is elastic, to prevent the secondary battery 20 under compression from being damaged. However, the material of the compression unit 200 is not necessarily limited thereto, and the compression unit 200 may be provided in the form of a non-elastic body.

For reference, in the case where the predetermined area of the secondary battery 20 (for example, defect-prone areas) is positionally changed from one side to the other side of the secondary battery 20 due to a future design change or the like, the compression unit 200, according to the present disclosure, can move on the base plate 100 to a position corresponding to the predetermined area. For this reason, there is an advantage in that the position of the compression unit 200 may actively correspond to a change in the position of the predetermined area of the secondary battery 20 without having to manufacture other additional inspection apparatuses 10.

In this case, the compression unit 200 may be provided to be movable on the base plate 100 along a longitudinal direction of the base plate 100.

In order to compress the predetermined area of the secondary battery 20, the compression unit 200 may stop at the position corresponding to the predetermined area of the secondary battery 20 while sliding along the longitudinal direction of the base plate 100 and then be fixed to the corresponding position.

In this case, the compression unit 200 may be guided on the base plate 100 by a guide unit 150.

In addition, the compression unit 200 may be provided in a shape that surrounds the base plate 100 from the outside, and the guide unit 150 may include: a guide groove 151 that is provided on one surface of the base plate 100; and a guide protrusion 152 that is provided on one surface of the compression unit 200 to engage slidably with the guide groove 151.

Specifically, the compression unit 200 may be provided with a hollow portion 210 so that the base plate 100 is insertable thereinto. In addition, the compression unit 200 may be provided as a structure having a shape (for example, a rectangular shape) that continuously extends while bending several times to surround the base plate 100 from the outside.

While the compression unit 200 provided may be entirely made of an elastic material, the compression unit 200 may be provided such that only the opposing surfaces of the compression unit 200, which apply compression to the secondary battery 20, are partially elastic. Furthermore, additional elastic pads are installable only on the opposing surfaces of the compression unit 200, so modifications and alternatives may be appropriately made as needed.

In addition, referring to FIGS. 1 and 3, the guide unit 150, configured to allow the compression unit 200 to be guided and move along a predetermined route on the base plate 100, may include the guide groove 151 and the guide protrusion 152.

The guide groove 151 may be formed in a recessed manner on one surface of the base plate 100. In this case, one surface of the base plate 100 may be the upper surface 120. In addition, the guide protrusion 152, configured to engage slidably with the guide groove 151, may be formed to protrude from one surface of the compression unit 200. In this case, one surface of the compression unit 200 may be an upper bottom surface of the compression unit 200.

In the meantime, although FIGS. 1 and 3 illustrate that the guide groove 151 is formed on the base plate 100 while the guide protrusion 152 is formed on the compression unit 200, this is merely one example. Unlike what is illustrated in the drawings, it is also possible that the guide groove 151 is formed on one surface of the compression unit 200 while the guide protrusion 152 is formed on one surface of the base plate 100.

The separator defect inspection apparatus 10 for a secondary battery, according to one embodiment of the present disclosure, may further include a position fixing unit 300 so that the compression unit 200 is fixed to a specific position of the base plate 100.

The position fixing unit 300 may be provided to ensure that when the compression unit 200, which has been sliding along the longitudinal direction of the base plate 100, reaches the specific position corresponding to the predetermined area of the secondary battery 20, the compression unit 200 is fixed to the specific position, rather than randomly traveling. When the compression unit 200 is fixed to the specific position on the base plate 100 by the position fixing unit 300, the compression test may be performed on the secondary battery 20 by the compression unit 200.

The position fixing unit 300 may include: a first position fixing hole 310 that is provided on one surface of the base plate 100 at predetermined intervals along the longitudinal direction of the base plate 100; a second position fixing hole 320 that is provided on one surface of the compression unit 200 to correspond to the first position fixing hole 310; and a fixing pin 330 that passes through the second position fixing hole 320 and is inserted into the first position fixing hole 310 to positionally fix the compression unit 200 to the base plate 100 (see FIG. 1).

The first position fixing hole 310 may be formed on one surface of the base plate 100 (for example, the upper surface 120), and a plurality of first position fixing holes 310 may be provided. The plurality of first position fixing holes 310 may be provided at predetermined intervals along the longitudinal direction of the base plate 100.

In this case, the predetermined intervals at which the first position fixing holes 310 are formed may be uniformly spaced by a constant distance or unevenly spaced by varying distances, which may be appropriately selected as needed.

The second position fixing hole 320 may be formed on one surface of the compression unit 200 (for example, the upper surface) while passing therethrough to correspond to the first position fixing hole 310. Although a single second position fixing hole 320 may be provided, a plurality of second position fixing holes 320 may be provided for stable fixation and engagement. When the plurality of second position fixing holes 320 is provided, the distance by which the second position fixing holes 320 are spaced from each other may be determined in consideration of the intervals between the first position fixing holes 310.

The fixing pin 330 passes through the second position fixing hole 320 of the compression unit 200, arranged outside the base plate 100, and is then inserted into the first position fixing hole 310 to positionally fix the compression unit 200 to the specific position of the base plate 100.

In other words, when the compression unit 200 reaches the specific position while positionally moving on the base plate 100, the fixing pin 330 may be inserted into the second position fixing hole 320 and the first position fixing hole 310 so that the compression unit 200 is fixed to the corresponding position.

In this case, the fixing pin 330 may include: a head portion 331; and a pin portion 332 that extends from the head portion 331 and is provided insertably into the second position fixing hole 320 and the first position fixing hole 310 (see FIGS. 1 and 3).

The head portion 331, configured to be positioned on the upper side of the fixing pin 330, may be provided in a shape or structure that allows the fixing pin 330 to be held by the user's hands. In addition, the pin portion 332, configured to extend from the head portion 331 by a predetermined length in a downward direction, may be inserted into the first position fixing hole 310 by passing through the second position fixing hole 320 of the compression unit 200 arranged outside the base plate 100. In this case, the number of pin portions 332 and the distance by which the pin portions 332 are spaced from each other may be determined in consideration of the number of second position fixing holes 320 and the distance by which the second position fixing holes 320 are spaced from each other.

In addition, at least a portion of an upper part of the head portion 331 may include an inclined portion 331a whose width gradually increases from top to bottom to guide the secondary battery 20 to enter in position.

Although the inclined portion 331a may be formed on at least a portion of the upper side of the head portion 331, in the head portion 331, the inclined portion 331a may be formed on a surface facing between a plurality of neighboring base plates 100 to guide the secondary battery 20 to enter in position. In this case, the inclined portion 331a may be formed in a structure whose width gradually increases from the top of the head portion 331 to the bottom of the inclined portion 331a.

In this case, a maximum protrusion of the inclined portion 331a may be provided such that the fixing pin 330, when inserted into the second position fixing hole 320 and the first position fixing hole 310, protrudes further compared to the respective outer surfaces of the base plate 100 and the compression unit 200 in the thickness directions thereof (see FIG. 3).

In other words, the maximum protrusion of the inclined portion 331a is provided such that the fixing pin 330, installed on the upper part of the base plate 100 and the compression unit 200, protrudes further compared to one that protrudes more among the outer surface of the base plate 100 in the thickness direction (front-to-rear direction in the drawings) or the outer surface of the compression unit 200 in the thickness direction (front-to-rear direction in the drawings). Thus, when the secondary battery 20 enters between a plurality of fixing pins 330 during the compression test, the secondary battery 20 may be guided to be in position without making contact with either the outer surface of the base plate 100 or the outer surface of the compression unit 200.

Accordingly, as illustrated in FIG. 4, when the secondary battery 20 enters between a plurality of inspection apparatuses 10 according to one embodiment of the present disclosure for the compression test of the secondary battery 20, the secondary battery 20 is guided to slide and enter in position by the inclined portion 331a of the fixing pin 330 even in the case where the secondary battery 20 fails to enter precisely between the fixing pins 330 (in position) but enters lopsided toward one of the fixing pins 330, ultimately allowing the secondary battery 20 to be in position.

In the meantime, as illustrated in FIG. 5, the separator defect inspection apparatus 10 for a secondary battery, according to one embodiment of the present disclosure, may further include an interleaving sheet 400 that is removably inserted between the inspection apparatus 10 and another neighboring inspection apparatus 10 to protect the secondary battery 20.

The interleaving sheet 400 may be provided to prevent at least one of the secondary battery 20 and the inspection apparatus 10 from being damaged by direct contact between the inspection apparatus 10, according to one embodiment of the present disclosure, and the secondary battery 20 and to protect the secondary battery 20.

Although the interleaving sheet 400 provided may be made of a paper material that is relatively lightweight, inexpensive, easily replaceable, and easy to mold and dispose of, the interleaving sheet 400 is not necessarily made of a paper material, and other materials may be used.

Specifically, the interleaving sheet 400 may include a main body portion 410 that is inserted between a plurality of neighboring separator defect inspection apparatuses 10 and is bent several times to provide an accommodation space capable of accommodating the secondary battery 20 thereinside.

The main body portion 410, configured to form the overall appearance of the interleaving sheet 400, may be arranged between the plurality of neighboring inspection apparatuses 10. The main body portion 410 may be provided to be bent or folded several times at a corresponding portion to face the upper surface 120 and wall 110 of the base plate 100 and the upper surface and compressing surface of the compression unit 200.

Accordingly, opposing ends of the main body portion 410 may be planarly molded to be placed respectively on the upper surfaces of different inspection apparatuses 10. In addition, predetermined points of the opposing ends of the main body portion 410 may be perforated by the pin portion 332 of the fixing pin 330 inserted into the first position fixing hole 310 and the second position fixing hole 320, so the interleaving sheet 400 may be fixed onto the upper surfaces of the inspection apparatuses 10, respectively.

The accommodation space capable of accommodating the secondary battery 20 may be formed inside the main body portion 410. This accommodation space provided may be formed by two opposing surfaces 410a, which are formed to be spaced while facing each other in the main body portion 410 and are bent at each of the opposing ends of the main body portion 410, and by a bottom surface connecting the opposing surfaces 410a at the lower side. This accommodation space may be laterally open.

In addition, the interleaving sheet 400 may further include a side portion 420 that covers a lateral lower part of the accommodation space and connects the opposing surfaces 410a of the main body portion 410 that are spaced from each other.

The side portion 420 may be provided to connect the opposing surfaces 410a of the main body portion 410 at the lateral side to prevent the secondary battery 20, accommodated in the accommodation space, from escaping while covering the lateral lower part of the accommodation space without interfering with a tab portion 21 that protrudes in a lateral direction of the secondary battery 20.

Accordingly, as illustrated in FIG. 6, the side portion 420 may be provided to have a height lower than that of the tab portion 21 of the secondary battery 20 accommodated in the main body portion 410.

As the height of the side portion 420 is formed to be lower than that of the tab portion 21 of the secondary battery 20 by a predetermined distance d, the secondary battery 20 accommodated in the accommodation space is prevented from laterally escaping while the tab portion 21 that protrudes laterally from the secondary battery 20 is prevented from interfering with the side portion 420.

In the meantime, as illustrated in FIG. 7, the side portion 420 may include a plurality of creases 421 that are provided such that the side portion 420 folds along a compression direction (front-to-rear direction).

The creases 421 are formed in the side portion 420 in a height direction (vertical direction), and the plurality of these creases 421 may be provided to be spaced at predetermined intervals in the compression direction such that the side portion 420 folds along the compression direction when the inspection apparatus 10, according to one embodiment of the present disclosure, compresses the secondary battery 20.

As illustrated in FIGS. 6 and 7, when the compression test of the secondary battery 20 accommodated in the interleaving sheet 400 is performed so that the inspection apparatus 10, according to the present disclosure, moves toward the secondary battery 20 to compress the secondary battery 20, the side portion 420 may be prevented from being damaged and is enabled to be foldable in a uniform pattern by the creases even in the case where the interval between the opposing surfaces 410a of the main body portion 410 is reduced.

Furthermore, when the inspection apparatus 10 returns to its original position after the completion of the compression test, the side portion 420 unfolds and returns to its original state by the creases 421, thus preventing the side portion 420 from being damaged.

The present disclosure has been described in detail through specific embodiments. These embodiments are intended to specifically describe the present disclosure, and what is disclosed herein is only for illustrative purposes of the present disclosure, not for limiting the appended claims. It is apparent to those skilled in the art that various modifications and alternatives may be made to the embodiments without departing from the technical idea and scope of the present disclosure, and such modifications and alternatives fall within the scope of the appended claims.

What is claimed is:

1. A separator defect inspection apparatus for a secondary battery, the separator defect inspection apparatus comprising:
a base plate that is provided to be movable toward a secondary battery; and
a compression unit that provides a localized protrusion structure to an exterior of the base plate to compress a predetermined area of the secondary battery.

2. The separator defect inspection apparatus of claim 1, wherein the compression unit is provided to be movable on the base plate along a longitudinal direction of the base plate.

3. The separator defect inspection apparatus of claim 2, wherein the compression unit is guided on the base plate by a guide unit.

4. The separator defect inspection apparatus of claim 3, wherein the compression unit is provided in a shape that surrounds the base plate from the outside, and
the guide unit comprises:
a guide groove that is provided on one surface of the base plate; and
a guide protrusion that is provided on one surface of the compression unit to engage slidably with the guide groove.

5. The separator defect inspection apparatus of claim 3, further comprising a position fixing unit so that the compression unit is fixed to a specific position of the base plate.

6. The separator defect inspection apparatus of claim 5, wherein the position fixing unit comprises:
a first position fixing hole that is provided on one surface of the base plate at predetermined intervals along the longitudinal direction of the base plate;
a second position fixing hole that is provided on one surface of the compression unit to correspond to the first position fixing hole; and
a fixing pin that passes through the second position fixing hole and is inserted into the first position fixing hole to positionally fix the compression unit to the base plate.

7. The separator defect inspection apparatus of claim 6, wherein the fixing pin comprises:
a head portion; and
a pin portion that extends from the head portion and is provided insertably into the first and second position fixing holes.

8. The separator defect inspection apparatus of claim 7, wherein at least a portion of an upper part of the head portion comprises an inclined portion whose width gradually increases from top to bottom to guide the secondary battery to enter in position.

9. The separator defect inspection apparatus of claim 8, wherein a maximum protrusion of the inclined portion is provided such that the fixing pin, when inserted into the first and second position fixing holes, protrudes further compared to respective outer surfaces of the base plate and the compression unit in thickness directions thereof.

10. The separator defect inspection apparatus of claim 1, further comprising an interleaving sheet that is removably inserted between the separator defect inspection apparatus and another neighboring separator defect inspection apparatus to protect the secondary battery.

11. The separator defect inspection apparatus of claim 10, wherein the interleaving sheet comprises a main body portion that is inserted between a plurality of neighboring separator defect inspection apparatuses and is bent several times to provide an accommodation space capable of accommodating the secondary battery thereinside.

12. The separator defect inspection apparatus of claim 11, wherein the interleaving sheet further comprises a side portion that covers a lateral lower part of the accommodation space and connects opposing surfaces of the main body portion that are spaced from each other.

13. The separator defect inspection apparatus of claim 12, wherein the side portion is provided to have a height lower than that of a tab portion of the secondary battery accommodated in the main body portion.

14. The separator defect inspection apparatus of claim 12, wherein the side portion comprises a plurality of creases that are provided such that the side portion folds along a compression direction.
